(19) United States
(12) Patent Application Publication
(10) Pub. No.: US 2023/0147463 A1
(43) Pub. Date: May 11, 2023

(54) OPTICAL ELEMENT FOR THE VUV WAVELENGTH RANGE, OPTICAL ARRANGEMENT, AND METHOD FOR MANUFACTURING AN OPTICAL ELEMENT

(71) Applicant: Carl Zeiss SMT GmbH, Oberkochen (DE)

(72) Inventors: Felix LANGE, Giengen an der Brenz (DE); Larissa WALTER, Aalen (DE)

(21) Appl. No.: 18/090,067

(22) Filed: Dec. 28, 2022

Related U.S. Application Data
(63) Continuation of application No. PCT/EP2021/064874, filed on Jun. 2, 2021.

(30) Foreign Application Priority Data
Jun. 29, 2020 (DE) 10 2020 208 044.5

(51) Int. Cl. G02B 1/14; G02B 5/08; G03F 7/20

(52) U.S. Cl. CPC G02B 1/14; G02B 5/0891; G03F 7/70316

(57) ABSTRACT

An optical element (7, 8) for the VUV wavelength range includes a substrate (7a, 8a), and a coating (15) applied to the substrate (7a, 8a). The coating (15) has at least one fluorine scavenger layer (17, 17a, . . . , 17n) having a fluoride material (M^{x+}Fₓ⁻) doped with at least one preferably metallic dopant ion (A^{x+}). Also described are an optical arrangement that includes at least one such optical element (7, 8), as well as a method for producing such an optical element (7, 8).

### CROSS-REFERENCE TO RELATED APPLICATION

This is a Continuation of International Application PCT/EP2021/064874, which has an international filing date of Jun. 2, 2021, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2020 208 044.5 filed on Jun. 29, 2020.

### FIELD OF THE INVENTION

The invention relates to an optical element for the VUV wavelength range, comprising: a substrate, and a coating applied to the substrate. The invention also relates to an optical arrangement for the VUV wavelength range, for example a wafer inspection system or a VUV lithography system having at least one optical element formed as described above, and to a method for producing an optical element, comprising: applying a coating to a substrate.

### BACKGROUND

In the context of this application, the very ultraviolet (VUV) wavelength range is understood to mean a wavelength range between 100 nm and 200 nm (VUV wavelength range according to DIN 5031 Part 7).

Optical arrangements or systems that are designed for the VUV wavelength range and are suitable, for example, for the inspection of wafers (cf., for example, US 2016/0258878 A1) require broadband, irradiation-stable optical elements such as mirrors, windows or beam dividers.

In particular for wavelengths of less than 160 nm, it is challenging to develop coatings or layers having a long lifetime when subjected to irradiation at high powers. One reason for this is that, in the case of irradiation at these wavelengths, the energy of the light is sufficient to generate defects in the layer via one-photon processes. The generation of defects (e.g. F centers) constitutes the start of a degradation process in fluoride layers in the case of irradiation with radiation in the VUV wavelength range, which may have the following steps, for example:

1. Absorption of radiation in the VUV wavelength range with energies close to the band edge of fluoride, and then excitation of electrons into the conduction band and/or exciton states and/or defect states close to the band edge
2. Relaxation of the previously excited electrons with release of the energy difference to the ionic lattice (color centers).
3. As a consequence of this mechanism, generation of fluorine defects and interstitial fluorine
4. Diffusion of fluorine atoms and loss of fluorine via the surface
5. Oxidation of the metal atom of the fluoride and enhancement of the absorption of the layer

There are various known approaches for improving the laser stability of fluoridic materials or for avoiding the above-described degradation process.

DE102019219177.0 proposes avoiding the decrease in reflectivity of mirrors manufactured from aluminum and protected with dielectric materials, for example with fluoridic materials such as MgF₂, by using a Mangin mirror for the VUV wavelength range.

PCT/EP2019/083632 describes an optical arrangement in the form of a wafer inspection system having a gas inlet designed or configured for supply of an adsorbate, especially of water, to the interior at least during the irradiation of the surface. The supply of the adsorbate to the surface of an optical element disposed therein is intended to alleviate the degradation of the surface.

US 2010/0108958 A1 describes an optical element for transmission of radiation at wavelengths below 250 nm that is said to have improved laser stability. The optical element consists of a calcium fluoride crystal doped with at least one material intended to prevent the formation of Ca colloids. The Ca colloids formed as a result of the combination of Ca with F centers are considered to be the cause of the reduction of laser stability of the optical element. F centers form when fluorine from the bulk of the optical element arrives at the surface and thence is released to the environment. The optical element may have a coating with at least one material selected from the groups of: fluorides, oxides and fluorinated oxides.

US 2003/0094129 A1 describes a crystal material for use in a refractive lithography system at wavelengths below 160 nm, comprising an alkali metal-alkaline earth metal solid solution, an alkaline earth metal-alkaline earth metal solid solution or an alkaline earth metal-lanthanum solid solution.

EP 1 394 590 A1 describes a method for preparing a calcium fluoride crystal having a sodium concentration of less than about 0.2 ppm. Such a crystal is said to have high laser stability on irradiation with laser radiation at a wavelength of 193 nm.

WO 2008/071411 A1 describes an optical element having a main body composed of a metal fluoride having elevated laser stability, to which optionally a coating is applied with at least one layer of a metal fluoride solid solution. The metal fluoride solid solution may have the composition (MFₙ)₁₋ₓ(RFₙ₊ₘ)ₓ where M denotes a chemical element of the first or second group of the Periodic Table, R an element of the second, third or fourth group of the Periodic Table, and n and m are integers.

DE 10 2018 211 498 A1 describes an optical arrangement comprising at least one reflective optical element in the form of a polished metal or silicon surface. The reflective face may have a protective layer having one or more laminas of a material from the group of AlF₃, LiF, NaF, MgF₂, CaF₂, LaF₃, GdF₃, HoF₃, ErF₃, Na₃AlF₆, Na₅Al₃F₁₅, ZrF₄, HfF₄, SiO₂, Al₂O₃, MgO and combinations thereof.

DE 10 2018 211 499 A1 discloses a method for producing a reflective optical element for the VUV wavelength range. The lifetime of the reflective optical element is extended by applying at least one first and one second lamina to a substrate, wherein one of the two laminas is a metal fluoride lamina and the other is an oxide lamina. The oxide lamina is intended to protect the layers beneath. DE 10 2018 211 499 A1 also states that oxide laminas at wavelengths of less than 160 nm can lead to large reflection losses. The reflectivity loss is to be reduced by the positioning of the oxide lamina in a region of low field strength.

### SUMMARY

It is an object of the invention to specify an optical element, an optical arrangement having at least one such optical element, and a method for producing an optical element, which enable a prolonged lifetime in the case of irradiation with radiation in the VUV wavelength range.

This object is achieved in one aspect by an optical element of the type specified at the outset, in which the coating has at least one fluorine scavenger layer comprising a fluoride material doped with at least one preferably metallic dopant ion.

What is proposed in accordance with the invention is to increase the lifetime of the optical element, especially in the case of irradiation with radiation at VUV wavelengths of less than 160 nm close to the band edge of the fluoride material, by interrupting the degradation process described above at step 4. This is accomplished by significantly reducing the mobility of the interstitial fluorine atoms with so-called “fluorine scavengers” in the fluorine scavenger layer. The optical element may be a fluoridic functional optical element or a fluoridically protected optical element, for example an (Al) mirror or a fluoridically protected transmitting optical element.

For creation of the “fluorine scavenger” effect, it is proposed that the fluoride material (e.g. LaF₃) of the fluorine scavenger layer, which is typically an ionic crystal, be doped with a (positively charged) dopant ion (cation, e.g. Gd³⁺). This cation can bind the fluorine atoms/fluoride ions generated by one-photon processes in the VUV irradiation within the layer and hence counteract fluorine loss through the surface. Specifically, the dopant ion (e.g. Gd³⁺) together with the interstitially diffusing fluorine/fluoride (in the present case, for example, as an H center (F₂⁻ interstitial) or Vₖ center defect (F₂⁻ coupling via two adjacent lattice sites)) forms a complex that reduces the mobility of the fluorine species.

The doping of halides, especially of fluorides, is known from photostimulatable x-ray storage films (“storage phosphors”) in electronically readable x-ray dosimeters. Electron-hole pairs generated in the irradiation of the material of such an x-ray storage film, e.g. BaFBr:Eu²⁺ or CsBr:Eu²⁺, are trapped locally on account of the doping in order to generate a latent image or to store information; cf., for example, the article “Photostimulable X-Ray Storage Phosphors: a Review of Present Understanding”, H. von Seggern, Braz. Jour. Phys. 29, 254-267 (1999) or the article “Storage Phosphors for Medical Imaging”, P. Leblans et al., Materials 4, 1034-1086 (2011).

The optical element of the invention utilizes the doping in order to avoid or at least significantly slow the diffusion of fluorine atoms. This exploits the fact that the same defects are initially generated in the respective fluoride material on irradiation with x-radiation as on irradiation with radiation in the VUV wavelength range.

In one embodiment, the coating has at least one fluoride layer, and the fluorine scavenger layer is applied to a side of the fluoride layer remote from the substrate. In this case, the fluorine scavenger layer serves to prevent the diffusion of fluorine from the fluoride layer into the environment. However, it is not absolutely necessary for the coating to include a fluoride layer and a fluorine scavenger layer applied thereto; instead, the coating may include solely a fluorine scavenger layer (without a fluoride layer) that serves, for example, as protective layer for a transparent substrate, for a mirror, etc.

In one embodiment, the fluoride material has a preferably metallic host lattice ion, the ionic radius of which differs by not more than 20%, preferably by not more than 15%, from an ionic radius of the dopant ion. In general, a small deviation (of less than 15%) between the ionic radius of the dopant ion and the ionic radius of the cation of the fluoride material is required in order to form a stable solid solution or stable layer (Vegard's law).

The deviation of the ionic radius R_{I} of the (metallic) host lattice ion of the fluoride material from the ionic radius R_{D} of the dopant ion is determined here by the following formula:

(R_{I}−R_{D})/R_{I}

In a further embodiment, the host lattice ion of the fluoride material has the same valency (ionic charge) as the dopant ion. This is a sufficient condition for the stability of the ionic lattice, but not a necessary condition: For x-ray storage films, it has been documented that it is possible to use metallic dopant ions (e.g. based on Mg, Ti, Ce) of different valency (2-valent, 3-valent, . . . ) in the case of monovalent host lattices, for example Li⁺F⁻.

In a further embodiment, the dopant ion has an electron configuration with at least one unpaired valency electron, preferably an electron configuration with a half-filled orbital. Unpaired valency electrons of the dopant ion are generally required for complexation with the interstitial fluorine. If the dopant ion has a half-filled orbital, i.e. it has half the number of the maximum possible number of valency electrons for the respective orbital, this is a chemically particularly stable configuration. The condition specified here is also a sufficient condition, but not a necessary condition, on the dopant ions of the fluorine scavenger layer. For example, in the case of x-ray storage films, combinations such as KbR:In⁺ or RbBr:Ga⁺ have been documented, in the case of which the s ion pairs appear to function as halogen scavengers.

In a further embodiment, the fluorine scavenger layer is transparent to radiation in the VUV wavelength range. On irradiation with radiation in the VUV wavelength range, the fluorine scavenger layer should absorb a minimum amount of radiation in order to avoid degradation. Transparency of the fluorine scavenger layer is generally also required when the optical element is a transmitting optical element. The dopant ion should therefore be chosen such that the absorption thereof for VUV radiation is at a minimum.

In one embodiment, the dopant ion is selected from the group comprising: Gd³⁺, Eu²⁺, Mn²⁺, Fe³⁺, Ru³⁺ and T1⁺. These dopant ions meet the above-formulated condition with regard to electron configuration and have comparatively low absorption for radiation in the VUV wavelength range. It is also possible to combine these dopant ions with metallic host lattice ions of the fluoride material that have a suitable ionic radius and possibly the same valency (see below).

In a further embodiment, the fluoride material has a host lattice ion selected from the group comprising: Li⁺, Na⁺, K⁺, Rb⁺, Mg²⁺, Ca²⁺, Sr²⁺, Ba²⁺, Al³⁺, La³⁺ and Y³⁺. Fluoride materials having cations from the (nonexhaustive) list of materials given here have been found to be of good suitability for the formation of a fluorine scavenger layer.

In principle, the doped fluoride material of the fluorine scavenger layer (i.e. the material of the fluorine scavenger layer) should generally have the following chemical structural formula (in the absence of a solid solution; see below):

M^{x+}Fₓ⁻:A^{x+},

where M denotes the (generally metallic) atom of the host lattice ion M^{x+} of the fluoride material (e.g. Mg, La, . . . ), A the dopant atom of the dopant ion A^{x+} (e.g. Gd, Mn, Eu, . . . ), and x the valency (ionic charge) of the metal atom M or dopant atom A.

In a further embodiment, the doped fluoride material of the fluorine scavenger layer is selected from the group comprising: RbF:TI⁺, KF:TI⁺, MgF₂:Mn²⁺, SrF₂:Eu²⁺, BaF₂:Eu²⁺, LaF₃:Gd³⁺, YF₃:Gd³⁺, AlF₃:Fe³⁺. These materials satisfy the above-specified chemical structural formula and the further conditions mentioned above on the ionic radii, valency and electron configuration of the dopant ions, and are therefore particularly suitable as fluorine scavenger layers.

The dopant ion in the doped fluoride material may have a comparatively low concentration between 0.1 at. % and 2.0 at. %, or between 0.2 at. % and 1.0 at. %. Such a range of values for dopant concentration, which is in the order of magnitude of the dopant concentration of the materials of x-ray storage films, has been found to be favorable.

In a further embodiment, the dopant ion is present in a further fluoride material that forms a solid solution (an alloy in the case of metallic cations) with the fluoride material. Two fluoride materials having a defined composition in this case form what is called a solid solution series having the chemical composition

(M^{x+}Fₓ⁻)_{y}(A^{x+}Fₓ⁻)_{1-y}

where y may assume values of y=0 to y=1, preferably of y=0.1 to y=0.9. In the context of this application, a solid solution is also understood to mean a pseudo-binary mixture of two fluorides having miscibility gaps in the phase diagram.

One example of a solid solution or of a pseudo-binary series is the solid solution (LaF₃)₍₁₋ₓ₎(GdF₃)ₓ with x=0 . . . 1. A fluorine scavenger layer in the form of a solid solution can be applied in a simple manner (by coevaporation, see below). In the case of dielectric applications, for example in the case of reflection or antireflection coatings, it is necessary in this case to take account of the values of the real part n and the imaginary part k of the two fluoride materials of the solid solution for the respective coating design.

In a further embodiment, the fluorine scavenger layer forms a capping layer of the coating, or the fluorine scavenger layer forms a diffusion barrier between the fluoride layer and a further layer of the coating, especially a further fluoride layer. In the former case, the fluorine scavenger layer forms the uppermost layer of the coating, i.e. that layer furthest removed from the substrate.

The fluorine scavenger layer in this case serves to prevent fluorine from escaping from the underlying fluoride layer into the environment. However, it is also possible that the fluorine scavenger layer is disposed between the fluoride layer and a further layer, for example a further fluoride layer, and acts as a diffusion barrier between the two surrounding layers. It will be apparent that one and the same coating may have both a fluorine scavenger layer as capping layer of the coating and at least one further fluorine scavenger layer as diffusion barrier.

In a further embodiment, the coating forms a (highly) reflective coating or an antireflection coating. In both cases, the coating may form a multilaminar coating having a multitude of layer pairs with two layers each having different refractive indices. On account of the doping or possibly for other reasons, the fluorine scavenger layer has a refractive index that typically varies from the refractive index of the fluoride layer to which it is applied. Therefore, the fluorine scavenger layer and the fluoride layer may form a layer pair of a functional multilaminar coating.

The coating in this case typically has a defined number of layer pairs having generally identical thickness in order to create the reflective effect or the antireflection effect of the coating through interference effects. In this embodiment, the fluorine scavenger layer thus fulfills a twin function since it not only prevents the diffusion of fluorine atoms or acts as a protective layer, but also has an optical effect and contributes to the reflective or antireflection effect of the coating.

If the coating is a reflective coating, the optical element is typically a reflective optical element, for example a mirror. The mirror or reflective coating in this case may, for example, have an aluminum layer, the reflective effect of which is enhanced by the fluoride layers or fluorine scavenger layer(s) in its reflective effect. At the same time, the fluoride layers or fluorine scavenger layer(s) also serve to protect the aluminum layer from degradation.

If the coating takes the form of an antireflection coating, the optical element typically takes the form of a transmissive optical element. In this case, the optical element may have, for example, a preferably crystalline, especially ionic, substrate formed, for example, from MgF₂, CaF₂, LiF,

A further aspect of the invention relates to an optical arrangement for the VUV wavelength range, especially a wafer inspection system or a VUV lithography apparatus, comprising: at least one optical element as described above.

The optical element may be a reflective optical element for radiation in the VUV wavelength range, or may alternatively be a transmissive optical element designed for passage of radiation in the VUV wavelength range. The optical element may alternatively be a beam divider that either transmits or reflects radiation depending on the wavelength or, for example, the polarization of the radiation in the VUV wavelength range.

A further aspect of the invention relates to a method of the type specified at the outset, in which at least one fluorine scavenger layer is applied in the application of the coating, wherein the fluorine scavenger layer includes a fluoride material doped with at least one dopant ion. There are various options for the application of the fluorine scavenger layer, which is typically effected by deposition from the gas phase or by another type of coating method.

Preferably, the fluorine scavenger layer is applied by simultaneous deposition of the fluoride material and a further fluoride material containing the dopant ion. In this variant of the method, the fluorine scavenger layer is deposited by coevaporation of two fluoridic (transparent) materials. In this case, typically two evaporator sources are used for the deposition, one of which contains the fluoride material of the fluoridic crystal lattice and the other of which includes a fluoride material containing the dopant ion. The deposition in this case can form a pseudo-binary mixture of the two fluorides (e.g. LaF₃ and GdF₃ to give LaF₃:Gd³⁺, for example in the form of (LaF₃)₁₋ₓ (GdF₃)ₓ, x=0 to 1, i.e. the deposition forms a solid solution that does not have any miscibility gaps in the phase diagram. For the co-deposition, it is favorable when the two fluoride materials take the form of a coating material, are non-hygroscopic and are not associated with any handling concerns (i.e. there are no hazard or safety messages, and there is no endangerment of health or the environment).

In an alternative variant, the fluorine scavenger layer is applied by deposition of the fluoride material doped with the dopant ion. In this case, via a suitable synthesis, the fluoride material that constitutes the host lattice for the doping is doped beforehand with a suitable fluorine scavenger material or with a suitable dopant ion. The pre-doped material of the fluorine scavenger layer in this case is transferred stoichiometrically to the substrate or to the fluoride layer in a subsequent coating method, for example by deposition from the gas phase.

In a further variant, the coating includes at least one fluoride layer, and the at least one fluorine scavenger layer is applied on a side of the fluoride layer remote from the substrate. In general, the fluorine scavenger layer is applied directly to the fluoride layer in order to avoid diffusion of fluorine into layers in between, but this is not absolutely essential.

Further features and advantages of the invention will be apparent from the description of working examples of the invention that follows, with reference to the figures of the drawing, which show details essential to the invention, and from the claims. The individual features can each be implemented alone or in a plurality in any combination in one variant of the invention.

### BRIEF DESCRIPTION OF THE DRAWINGS

Working examples are shown in the schematic drawing and are explained in detail in the description that follows. The figures show:

FIG. 1 a schematic diagram of an optical arrangement for the VUV wavelength range in the form of a VUV lithography apparatus,

FIG. 2 a schematic diagram of an optical arrangement for the VUV wavelength range in the form of a wafer inspection system,

FIGS. 3A and 3B schematic diagrams of a transmitting optical element having a coating with a fluorine scavenger layer as capping layer (FIG. 3A), and of a reflective optical element having a reflective coating with a multitude of fluorine scavenger layers (FIG. 3B), and

FIGS. 4A and 4B schematic diagrams of a substrate of an optical element on deposition of the fluorine scavenger layer either stoichiometrically (FIG. 4A) or simultaneously through co-evaporation (FIG. 4B).

### DETAILED DESCRIPTION

In the description of the drawings that follows, identical reference signs are used for components that are the same or analogous or have the same function or the analogous function.

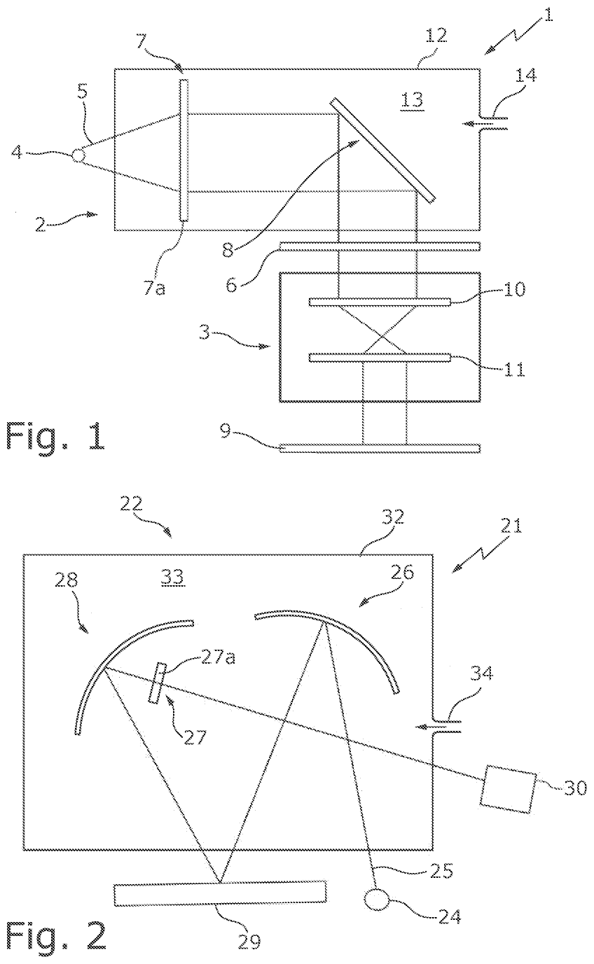

FIG. 1 shows a schematic of an optical arrangement 1 in the form of a VUV lithography apparatus, in particular for wavelengths in the range of between 100 nm and 200 nm or 160 nm. The VUV lithography apparatus 1 has, as primary components, two optical systems in the form of an illumination system 2 and a projection system 3. For the performance of an exposure process, the VUV lithography apparatus 1 has a radiation source 4 which may, for example, be an excimer laser which emits radiation 5 at a wavelength in the VUV wavelength range of, for example, 193 nm, 157 nm or 126 nm and may be an integral part of the VUV lithography apparatus 1.

The radiation 5 emitted by the radiation source 4 is processed with the aid of the illumination system 2 in a manner such that a mask 6, also called reticle, can be fully illuminated thereby. In the example shown in FIG. 1, the illumination system 2 has both transmitting and reflective optical elements. In a representative manner, FIG. 1 shows a transmitting optical element 7, which focuses the radiation 5, and a reflective optical element 8, which deflects the radiation 5, for example. In a known manner, in the illumination system 2, a wide variety of transmitting, reflecting or other optical elements can be combined with one another in any manner, even in a more complex manner.

The mask 6 has, on its surface, a structure which is transferred to an optical element 9 to be exposed, for example a wafer, with the aid of the projection system 3 in the context of production of semiconductor components. In the example shown, the mask 6 is designed as a transmitting optical element. In alternative embodiments, the mask 6 may also be designed as a reflective optical element. The projection system 2 has at least one transmitting optical element in the example shown. The example shown illustrates, in a representative manner, two transmitting optical elements 10, 11, which serve, for example, to reduce the structures on the mask 6 to the size desired for the exposure of the wafer 9. In the case of the projection system 3 as well, it is possible for reflective optical elements among others to be provided, and for any optical elements to be combined with one another as desired in a known manner. It should be pointed out that optical arrangements without transmissive optical elements can also be used for VUV lithography.

FIG. 2 shows a schematic of an illustrative embodiment of an optical assembly in the form of a wafer inspection system 21. The explanations that follow are also analogously applicable to inspection systems for inspection of masks.

The wafer inspection system 21 has an optical system 22 with a radiation source 24, from which the radiation 25 is directed onto a wafer 29 by the optical system 22. For this purpose, the radiation 25 is reflected onto the wafer 29 by a concave mirror 26. In the case of a mask inspection system 2, it would be possible to dispose a mask to be examined in place of the wafer 29. The radiation reflected, diffracted and/or refracted by the wafer 29 is guided onto a detector 30 for further evaluation by a further concave mirror 28 that likewise forms part of the optical system 22 via a transmitting optical element 27. The radiation source 24 may, for example, be exactly one radiation source or a combination of multiple individual radiation sources, in order to provide an essentially continuous radiation spectrum. In modifications, it is also possible to use one or more narrowband radiation sources 24. Preferably, the wavelength or the wavelength band of the radiation 25 generated by the radiation source 24 lies in the range of between 100 nm and 200 nm, more preferably between 110 nm and 190 nm.

In the example shown in FIG. 1, the illumination system 2 has a housing 12 in which there is formed an interior 13 within which there are disposed the transmissive optical element 7 and the reflective optical element 8 in the form of the mirror. Correspondingly, the optical system 22 of the wafer inspection system 21 of FIG. 2 has a housing 32 in which there is formed an interior 33 in which there are disposed the two mirrors 26, 28 and the transmissive optical element 27.

The lithography apparatus 1 of FIG. 1 also has a gas inlet 14 that serves to feed an inert gas into the interior 13, for example in the form of a noble gas, i.e. in the form of He, Ne, Ar, Kr, Xe or in the form of nitrogen (N₂). Correspondingly, the wafer inspection system 21 of FIG. 2 also has a gas inlet 34 that serves for supply of an inert gas into the interior 33 of the housing 32 of the optical system 22.

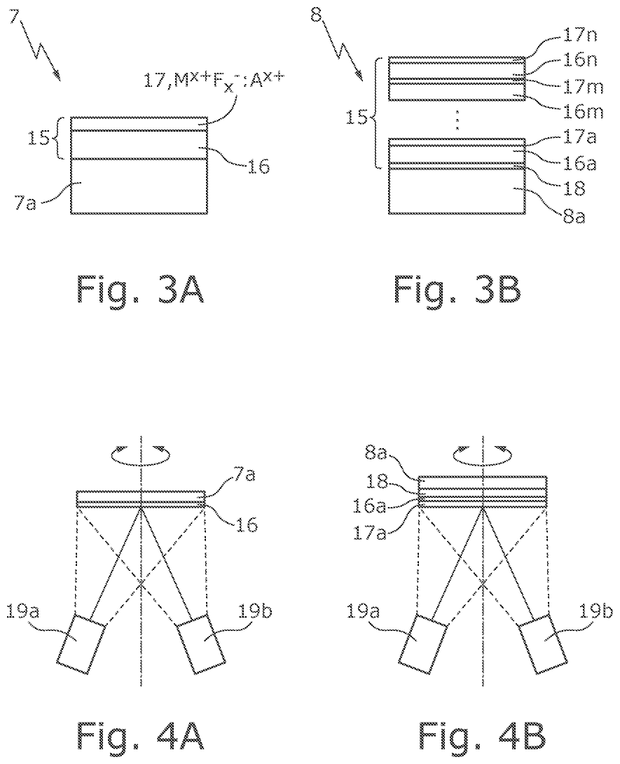

FIG. 3A shows, by way of example, the transmitting optical element 7 of FIG. 1 in a detail diagram. The transmitting optical element 7 has a substrate 7a of an ionic crystal, for example in the form of MgF₂, and is irradiated with radiation 5 from the radiation source 4 that typically has a high intensity. For protection of the substrate 7a, for example from a rearrangement in the irradiation, a coating 15 is applied to a surface of the substrate 7a and, in the example shown, has a fluoride layer 16, and a fluorine scavenger layer 17 applied thereto.

In the case of the irradiation of the optical element 7 with the radiation 5 in the VUV wavelength range, on account of the high radiation intensity, there can be degradation of the fluoride layer 16 in which fluorine defects are generated and interstitial fluorine is formed. In order to counteract the diffusion of fluorine atoms through the surface of the fluoride layer 16 into the environment, in the example shown in FIG. 3A, it is possible to apply a fluorine scavenger layer 17 to the fluoride layer 16. The material of the fluoride layer 16 may, for example, be MgF₂, AlF₃, LiF, LaF₃, GdF₃, BaF₂ or another transparent fluoride material.

The transmitting optical element 27 shown in FIG. 2 has a substrate 27a composed of an ionic crystal and a coating 15 (not shown pictorially), which differs from the coating 15 shown in FIG. 3A in that it has an individual layer in the form of a fluorine scavenger layer 17. The coating 15 of the transmitting optical element 27 thus consists of the fluorine scavenger layer 17, which may be formed in the same way as the fluorine scavenger layer 17 described in connection with FIG. 3A.

FIG. 3B shows, by way of example, the reflective optical element 8 of FIG. 1 in a detailed description. The reflective optical element 8 has a substrate 8a, for example composed of a fluoridic material or of silicon. A reflective coating 15 is applied to the substrate 8a for reflection of the VUV radiation 5. The reflective coating 15 comprises an aluminum layer 18 disposed adjacent to the substrate 8a, and a sequence of n pairs of layers, each having a fluoride layer 16a, . . . , 16n and a fluorine scavenger layer 17a, . . . , 17n applied to the respective fluoride layer 16a, . . . , 16n. It will be apparent that the coating may have just a single pair of layers 16a, 17a (n=1).

With the exception of the uppermost fluorine scavenger layer 17n, which forms the capping layer of the reflective coating 15, the fluorine scavenger layers 17a, . . . , 17m serve as diffusion barriers between every two adjacent fluoride layers 16b, . . . , 16n. The pairs of layers 16a, 17a, . . . , 16n, 17n serve firstly to protect the aluminum layer 18 from oxidation and secondly to increase the reflectivity of the coating 15 for the radiation 5 in the VUV wavelength range. Accordingly, the refractive indices of the respective pairs of layers 16a, 17a, . . . , 16n, 17n are matched to one another such that a high reflectivity is established within a desired wavelength range within the VUV wavelength range. It will be apparent that the reflective optical elements 26, 28 shown in FIG. 2 are also provided, or can be provided, analogously with a reflective coating 15.

In the case of the reflective optical element 8 shown in FIG. 3B, as in the case of the transmitting optical element 27, it is possible to apply just a single fluorine scavenger layer 17 to the aluminum layer 18, which serves as protective layer and as capping layer. It is thus not a requirement for the coating 15 of the reflective optical element 8 to have one or more fluoride layers 16a, . . . , 16n, as shown in FIG. 3B.

The pairs of layers 16a, 17a, . . . , 16n, 17n may also be applied to the transmitting optical element 7 shown in FIG. 3A, in order to form an antireflection coating rather than a reflective coating. For this purpose, the layer thicknesses and the pairs of materials of the respective pairs of layers 16a, 17a, . . . , 16n, 17n are adjusted suitably. It will be apparent that such an antireflection coating 15 does not have an aluminum layer, as is the case in the diagram shown in FIG. 3B.

In the case of the reflective optical element 8 shown in FIG. 3B as well, it is optionally possible to dispense with the aluminum layer 18, meaning that the reflective coating 15 may take the form of a dielectric multilayer coating having exclusively pairs of layers composed of a fluoride layer 16a, . . . , 16n, and a fluorine scavenger layer 17a, . . . , 17n applied to the respective fluoride layer 16a, . . . , 16n.

Rather than an antireflective effect, the coating 15 may also have a beam divider effect, i.e. transmit a first fraction of radiation and reflect a second fraction of radiation. The (partly) transmitting optical element 7, 27 in this case forms a beam divider.

The fluorine scavenger layer 17, 17a-17n shown in FIGS. 3A and 3B is formed from a fluoride material M^{x+}Fₓ⁺ as ionic host lattice, doped with at least one generally metallic dopant ion A^{x+}. The doped fluoride material of the fluorine scavenger layer 17, 17a-17n typically has the following chemical structural formula:

M^{x+}Fₓ ⁻:A^{x+}

where M denotes the (generally metallic) atom of the host lattice ion M^{x+} of the fluoride material, A the dopant atom of the dopant ion A^{x+}, and x the valency (ionic charge) of the metal atom or dopant atom.

Suitable materials for the dopant ion A^{x-} for production of a fluorine scavenger layer 17, which potentially forms a stable layer having a fluorine scavenger effect, may be selected using the criteria detailed in the following paragraphs:

A necessary property for the dopant ion A^{x-} is for it to have an ionic radius R_{D} similar to the ionic radius R_{I} of the (metallic) host lattice ion M^{x+} of the fluoride material M^{x+}Fₓ⁻. This means that the ionic radius R_{I} of the metallic host lattice ion M^{x+} should differ by not more than 20%, preferably by not more than 15%, from the ionic radius R_{D} of the dopant ion A^{x-} (or vice versa).

The deviation between the ionic radius R_{I} of the host lattice ion M^{x+} and the ionic radius R_{D} of the dopant ion A^{x-} is determined here by the following formula:

(R_{I}−R_{D})/R_{I}

A sufficient but not a necessary condition on the dopant ion A^{x-} is that the host lattice ion M^{x+} of the fluoride material M^{x+}Fₓ⁻ has the same valency x as the dopant ion A^{x+}. It is favorable, although not absolutely essential, for the host lattice ion M^{x+} and the dopant ion A^{x-} to have the same valency, i.e. the same ionic charge x.

For the fluorine scavenger layer 17, it is likewise favorable when the dopant ion A^{x-} has an electron configuration with at least one unpaired valency electron. Unpaired valency electrons of the dopant ion A^{x-} are generally required for complexation with the interstitial fluorine, which reduces the mobility of the fluorine species. In particular, an electron configuration with a half-filled orbital has been found to be advantageous: If the dopant ion A^{x-} has a half-filled orbital, this constitutes a chemically particularly stable configuration.

The fluorine scavenger layer 17 and also the fluoride layer 16 are generally transparent to the radiation 5 in the VUV wavelength range. The dopant ions A^{x-} should therefore not contain any material having high absorption in the VUV wavelength range.

Table 1 below gives suitable materials for host lattice ions M^{x+} and for dopant ions A^{x+}, and the ionic radii, coordination and electron configuration thereof. The values reported for the ionic radii are taken from the following source: “http://abulafia.mt.ic.ac.uk/shannon/ptable.php”.

TABLE 1

| | | | |
|---|---|---|---|
| | Ionic radius in | | Electron |
| Ion | ångströms | Coordination | configuration |

Host lattice ion M^{x+}

| | | | |
|---|---|---|---|
| Li⁺ | 0.76 | VI | [He] |
| Na⁺ | 1.02 | VI | [Ne] |
| K⁺ | 1.38 | VI | [Ar] |
| Rb⁺ | 1.52 | VI | [Kr] |
| Mg²⁺ | 0.72 | VI | [Ne] |
| Ca²⁺ | 1.00 | VI | [Ar] |
| Sr²⁺ | 1.18 | VI | [Kr] |
| Ba²⁺ | 1.35 | VI | [Xe] |
| Al³⁺ | 0.535 | VI | [Ne] |
| La³⁺ | 1.032 | VI | [Xe] |
| Y³⁺ | 1.04 | VI | [Kr] |

Dopant ion A^{x+}

| | | | |
|---|---|---|---|
| Gd³⁺ | 0.938 | VI | [Xe] 4f⁷ |
| Eu²⁺ | 1.17 | VI | [Xe] 4f⁷ |
| Mn²⁺ | 0.81 | VI (low spin) | [Ar] 3d⁵ |
| Fe³⁺ | 0.55 | VI (low spin) | [Ar] 3d⁵ |
| Ru³⁺ | 0.68 | VI | [Kr] 3d⁵ |
| TI⁺ | 1.5 | VI | [Xe] 3d¹⁰6s¹2p¹ |

With regard to the difference in their ionic radii, suitable pairs of host lattice ions M^{x+} or fluoride materials and dopant ions A^{x-} are given in table 2 below, in which possible combinations of fluoride materials for production of a respective fluorine scavenger layer 17, 17a, . . . , 17n by coevaporation (see below) are also described:

TABLE 2

| | Dopant | Difference in | Fluoride materials |
|---|---|---|---|
| Fluoride | ion | ionic radius | for coevaporation |
| RbF | Tl+ | 0.01% | RbF + TLF |
| KF | TI+ | −13.6% | KF + TlF |
| MgF₂ | Mn²⁺ | −12.5% | MgF₂ + MnF₂ |
| SrF₂ | Eu²⁺ | 0.8% | SrF₂ + EuF₂ |
| BaF₂ | Eu²⁺ | 13.3% | BaF₂ + EuF₂ |
| LaF₃ | Gd³⁺ | 9.1% | LaF₃ + GdF₃ |
| YF₃ | Gd³⁺ | 9.8% | YF₃ + GdF₃ |
| AlF₃ | Fe³⁺ | −2.8% | AlF₃ + FeF₃ |

Of the material combinations described above, the following have been found to be especially favorable: LaF₃:Gd³⁺, MgF₂:Mn²⁺, SrF₂:Eu²⁺, BaF₂:Eu²⁺, YF₃:Gd³⁺, AlF₃:Fe³⁺.

For all the combinations of materials described above for a fluoride scavenger layer 17, 17a, . . . , 17n, it is favorable when the dopant ion A^{x-} has a concentration in the doped fluoride material (M^{x+}Fₓ⁻: A^{x+}) of between 0.1 at % and 2.0 at %, especially between 0.2 at % and 1.0 at %.

If the concentration of the dopant ion A^{x-} is increased further, the fluorine scavenger layer 17, 17a, . . . , 17n typically forms a pseudo-binary mixture or a solid solution composed of the fluoride material M^{x+}Fₓ⁻ and a further fluoride material A^{x+}Fₓ⁻ having the chemical composition

(M^{x+}Fₓ⁻)_{y}(A^{x+}Fₓ⁻)_{1-y}

where y may assume values of y=0 to y=1, preferably of y=0.1 toy=0.9. Such a solid solution may be formed, for example, by coevaporation (see below).

The optical elements 7, 8 described in connection with FIGS. 3A and 3B may be produced, for example, in the manner described hereinafter in connection with FIGS. 4A and 4B. In the production of the respective optical element 7, 8, the respective substrate 7a, 8a is introduced into a coating system (not shown pictorially) in which there are disposed two evaporator sources 19a, 19b, each designed for evaporation of a fluoride material which is deposited on the substrate 7a, 8a. The substrate 7a, 8a is rotated about its center axis during the deposition, as indicated in FIGS. 4A and 4B.

In the example shown in FIG. 4A, in a first evaporation step, the fluoride layer 16 is deposited on the substrate 7a in that the first evaporator source 19a of the material of the fluoride layer 16, LaF₃ in the example shown, is evaporated. In the example shown in FIG. 4A, the host lattice material, LaF₃ in the present example, is doped beforehand with the dopant ion, e.g. Gd³⁺, and introduced into the second evaporator source 19b. Once the fluoride layer 16 having the desired thickness has been applied to the substrate 7a, the second evaporator source 19b is activated in order to stoichiometrically deposit the doped material of the fluorine scavenger layer, for example in the form of LaF₃:Gd³⁺, onto the fluoride layer 16.

In the example shown in FIG. 4B, the first fluoride layer 16a is deposited as described in connection with FIG. 4A, in that the first evaporator source 19a is activated. In the example shown in FIG. 4B, the second evaporator source 19b comprises a further fluoride material A^{x+}F⁻ₓ containing the dopant ion A^{x+} (in the present example: GdF₃). In this case, the first fluorine scavenger layer 17a is deposited by simultaneously activating the two evaporator sources (coevaporation), forming a pseudo-binary mixture or solid solution (LaF₃)₍₁₋ₓ₎(GdF₃)ₓ with x=0 . . . 1 of the two fluoride materials from the two evaporator sources 19a, 19b. The coevaporation in the case of the materials described in table 2 can be effected analogously to the manner described in connection with FIG. 4A.

In summary, the fluorine scavenger layer(s) 17, 17a, . . . , 17n described above can increase the lifetime of the respective optical elements 7, 8, 26, 27, 28, since the degradation of the respective fluoride layer(s) 16, 16a, . . . , 16n can be prevented or distinctly slowed. In this way, it is possible to dispense with the frequent exchange of the respective optical elements 7, 8, 26, 27, 28. It is typically likewise possible to dispense with the applying of protective layers of other materials, for example of oxidic materials, which generally have very high absorption at wavelengths of less than 160 nm. It is also possible to prevent the supply of gases intended to potentially protect the optical elements 7, 8, 26, 27, 28 on irradiation, or it is generally possible to distinctly reduce the concentrations or partial pressures of such gases.

What is claimed is:

1. An optical element for the very-ultraviolet (VUV) wavelength range, comprising:
a substrate, and a coating applied to the substrate,
wherein the coating has at least one fluorine scavenger layer comprising a fluoride material doped with at least one dopant ion, and
wherein the coating has at least one fluoride layer and the fluorine scavenger layer is applied to a side of the fluoride layer remote from the substrate.

2. The optical element as claimed in claim 1, wherein the dopant ion is a metallic dopant ion.

3. The optical element as claimed in claim 1, wherein the fluoride material has a host lattice ion, and an ionic radius of the host lattice ion differs by not more than 20% from an ionic radius of the dopant ion.

4. The optical element as claimed in claim 1, wherein the fluoride material has a metallic host lattice ion, and an ionic radius of the host lattice ion differs by not more than 15% from an ionic radius of the dopant ion.

5. The optical element as claimed in claim 3, wherein the host lattice ion of the fluoride material has a same valency as the dopant ion.

6. The optical element as claimed in claim 1, wherein the dopant ion has an electron configuration with at least one unpaired valence electron.

7. The optical element as claimed in claim 6, wherein the dopant ion has an electron configuration with a half-filled orbital.

8. The optical element as claimed in claim 1, wherein the fluoride scavenger layer is transparent to radiation in the VUV wavelength range.

9. The optical element as claimed in claim 1, wherein the dopant ion is selected from the group consisting essentially of: Gd³⁺, Eu²⁺, Mn²⁺, Fe³⁺, Ru³⁺ and TI⁺.

10. The optical element as claimed in claim 1, wherein the fluoride material has a host lattice ion selected from the group consisting essentially of: Li⁺, Na⁺, K⁺, Rb⁺, Mg²⁺, Ca²⁺, Sr²⁺, Ba²⁺, Al³⁺, La³⁺ and Y³⁺.

11. The optical element as claimed in claim 1, wherein the doped fluoride material of the fluorine scavenger layer is selected from the group consisting essentially of: RbF:TI⁺, KF:TI⁺, MgF₂:Mn²⁺, SrF₂:Eu²⁺, BaF₂:Eu²⁺, LaF₃:Gd³⁺, YF₃:Gd³⁺, AlF₃:Fe³⁺.

12. The optical element as claimed in claim 1, wherein the dopant ion is present in a further fluoride material that forms a solid solution with the fluoride material.

13. The optical element as claimed in claim 1, wherein the fluorine scavenger layer forms a capping layer of the coating or wherein the fluorine scavenger layer forms a diffusion barrier between the fluoride layer and a further layer.

14. The optical element as claimed in claim 13, wherein the further layer consists essentially of a further fluoride layer.

15. The optical element as claimed in claim 1, wherein the coating forms a reflective coating or an antireflection coating for radiation in the VUV wavelength range.

16. An optical arrangement configured for operation in the VUV wavelength range and comprising:
at least one optical element as claimed in claim 1, and configured as a wafer inspection system or as a VUV lithography apparatus.

17. A method for producing an optical element for the very ultraviolet (VUV) wavelength range, comprising:
applying a coating to a substrate,
wherein said applying of the coating comprises applying at least one fluorine scavenger layer, where the fluorine scavenger layer includes a fluoride material doped with at least one dopant ion,
wherein the coating comprises at least one fluoride layer, and
applying the at least one fluorine scavenger layer to a side of the fluoride layer remote from the substrate.

18. The method as claimed in claim 17, wherein the fluorine scavenger layer is applied by simultaneous deposition of the fluoride material and of a further fluoride material containing the dopant ion.

19. The method as claimed in claim 17, wherein the fluorine scavenger layer is applied by deposition of the fluoride material doped with the dopant ion.
